(19) United States
(12) Patent Application Publication
(10) Pub. No.: US 2024/0375209 A1
(43) Pub. Date: Nov. 14, 2024

(54) LASER IRRADIATING DEVICE, LASER IRRADIATING METHOD, AND LASER PROCESSING DEVICE

(71) Applicant: TOKYO SEIMITSU CO., LTD., Tokyo (JP)

(72) Inventor: Yusuke KANESHIRO, Hachioji-shi (JP)

(21) Appl. No.: 18/657,546

(22) Filed: May 7, 2024

(30) Foreign Application Priority Data
May 10, 2023 (JP) 2023-077969

(51) Int. Cl. B23K 26/046; B23K 26/03; H01L 21/67; H01L 21/78

(52) U.S. Cl. CPC B23K 26/046; B23K 26/032; H01L 21/67092; H01L 21/78

(57) ABSTRACT

A laser irradiating method includes: detecting a height position of a laser irradiation surface of a workpiece by focusing a distance measuring laser beam onto a planned irradiation line as an irradiation line preceding an irradiation line in a sub-scanning direction from a length measuring section (24) provided to be movable in a main scanning direction together with a laser irradiation section (22) and is provided at a position preceding the laser irradiation section in the sub-scanning direction; and controlling a height position of a focal point of a laser beam irradiated from the laser irradiation section when irradiating a laser beam from the laser irradiation section with a planned irradiation line as a new planned irradiation line on the basis of planned irradiation line information acquired from a detection result of the height position of the laser irradiation surface of the workpiece detected by the length measuring section.

### BACKGROUND OF THE INVENTION

### Field of the Invention

The present invention relates to a laser irradiating device, a laser irradiating method, and a laser processing device and particularly to laser beam irradiation control when performing laser processing or the like by focusing a laser beam onto a workpiece (for example, a wafer).

### Description of Related Art

In a device manufacturing process, a wafer on which semiconductor devices or electronic components have been formed is cut along planned dividing lines to divide the wafer into individual device chips. As a method of dividing a wafer, there is a method (a laser processing method or a laser dicing method) of cutting the wafer by irradiating a laser beam along the planned division line of the wafer.

As such a laser processing method, for example, there is a method (stealth dicing) in which a laser beam is focused inside a wafer to form a laser processing area that serves as a starting point for cutting inside the wafer and the wafer is cut by a cutting process such as expanding or breaking. Further, another example is a method of cutting a wafer by laser ablation processing (full cutting or grooving). Further, there is a method or the like of removing a laminated film (Low-k film) on a surface of a wafer by laser ablation processing, forming grooves using a laser, and cutting the wafer at a planned dividing line using a cutting process or fully cutting a remaining portion using a laser.

Further, there is also a method that combines laser dicing and blade dicing. For example, there is a method or the like of removing a laminated film on a surface of a wafer by a blade dicer, forming grooves by laser ablation processing, and cutting the wafer at a planned dividing line using a cutting process or fully cutting a remaining portion using a blade.

When performing laser processing as described above, a position (height) of a surface (hereinafter, referred to as a laser irradiation surface) irradiated with a laser beam in the wafer is detected and a position of a focal point of a laser beam is controlled according to the position of the laser irradiation surface of the wafer. At this time, the detection accuracy of the position of the laser irradiation surface of the wafer affects the processing quality of the chips. Especially in the case of internal focusing in which a laser beam is focused inside a silicon wafer, if there is an error in the detection result of the position of the laser irradiation surface of the wafer, the focal point of the laser beam may deteriorate due to the difference in refractive index between the atmosphere and silicon (the refractive index of silicon is about four times that of the atmosphere). For example, the position where the laser beam is incident and refracted may shift and the focal point of the laser beam may spread in the height direction due to an error between the detected position of the laser irradiation surface of the wafer and the actual position of the laser irradiation surface. In order to prevent such deterioration of the focal point, it is necessary to accurately detect the position of the laser irradiation surface of the wafer and to precisely control the position of the focal point of the laser beam according to the detection result.

Patent Document 1 discloses a laser processing device including a separate axial distance measuring sensor which is arranged on both sides of a focusing lens unit in a processing direction (X direction) and acquires displacement data of a laser beam irradiation surface of a workpiece without going through a focusing lens unit and a coaxial distance measuring sensor which acquires displacement data through a focusing lens unit. According to Patent Document 1, it is possible to control the focal point of the processing laser beam by following the detection result of the displacement of the laser beam incident surface of the workpiece.

### PATENT DOCUMENTS

[Patent Document 1] Japanese Unexamined Patent Application, First Publication No. 2019-025486

### SUMMARY OF THE INVENTION

However, as the processing speed of laser processing increases, it has become difficult to control the focal point of the processing laser beam in real time by following the detection result of the position of the laser irradiation surface of the wafer. For example, in Patent Document 1, displacement data is acquired by the separate axial distance measuring sensor and the coaxial distance measuring sensor that precede the processing direction. However, when the scanning speed of the processing laser beam is increased to increase the takt time, a delay occurs when controlling the focal point of the processing laser beam according to displacement data.

FIG. 7 is a graph illustrating an example in which a height of a focal point is controlled using a distance measuring sensor coaxial with a processing laser beam. In the graphs of FIGS. 7(a) to 7(c), the horizontal axis indicates the scanning direction (X direction) of the processing laser beam and the vertical axis indicates the height (Z). The dotted curves Da, Db, and Dc in the figure indicate the height of the laser irradiation surface of the wafer detected using a coaxial distance measurement sensor. Further, solid curves Ta, Tb, and Tc indicate waveforms when the focal point of the processing laser beam follows the detection results Da, Db, and Dc of the height of the laser irradiation surface of the wafer, respectively.

As illustrated in FIG. 7(a), there is a delay in the following waveform Ta of the focal point of the processing laser beam with respect to the height Da of the laser irradiation surface of the wafer. It is thought that such a delay in following the focal point of the processing laser beam with respect to the detection result of the height of the laser irradiation surface of the wafer increases as the scanning speed of the processing laser beam increases.

As illustrated in FIG. 7(b), when the height Db of the laser irradiation surface of the wafer changes periodically, a phase shift occurs between the height Db of the laser irradiation surface of the wafer and the following waveform Tb due to a delay in following the focal point of the processing laser beam with respect to the detection result of the height of the laser irradiation surface of the wafer. In this case, when the following waveform Tb has an opposite phase with respect to the height Db of the laser irradiation surface of the wafer due to the delay, the degree of deterioration of the focal point of the processing laser beam becomes larger.

In order to shorten the delay in following the focal point of the processing laser beam with respect to the detection result of the height of the laser irradiation surface of the wafer described above, for example, it is possible to shorten the communication cycle for detecting the laser irradiation surface of the wafer and controlling the focusing lens, or to improve the performance (for example, response speed) of the actuator for controlling the focusing lens. However, there are limits to shortening the communication cycle and improving actuator performance.

Further, in the case of using the separate axial distance measuring sensor and the coaxial distance measuring sensor preceding the processing direction, if there is an abnormality on the laser irradiation surface of the wafer (for example, if there is a location where the rate of change in unevenness is large due to adhesion of foreign matter or the like) as illustrated in FIG. 7(c), the abnormality cannot be detected until the planned dividing line where the abnormality exists is processed. For this reason, the laser processing is wasteful, and the efficiency of the laser processing is reduced.

The present invention has been made in view of such circumstances and an object of the present invention is to provide a laser irradiating device and a laser irradiating method capable of allowing a focal point of a laser beam to reliably follow a detection result of a laser irradiation surface of a wafer. Further, another object of the present invention is to provide a laser processing device capable of preventing a decrease in efficiency of laser processing.

In order to solve the above-described problems, according to a first aspect of the present invention, a laser irradiating device is provided including: a laser irradiation section which irradiates a laser beam onto an irradiation line extending in a main scanning direction of a laser irradiation surface of a workpiece; a length measuring section which is provided to be movable in the main scanning direction together with the laser irradiation section and is provided at a position preceding the laser irradiation section in a sub-scanning direction, the length measuring section being configured to detect a height position of the laser irradiation surface of the workpiece by focusing a distance measuring laser beam on a planned irradiation line corresponding to an irradiation line that precedes the irradiation line in the sub-scanning direction; and a control unit which controls a height position of a focal point of the laser beam irradiated from the laser irradiation section when irradiating the laser beam from the laser irradiation section with the planned irradiation line as a new planned irradiation line on the basis of planned irradiation line information acquired from a detection result of the height position of the laser irradiation surface of the workpiece detected by the length measuring section.

According to a second aspect of the present invention, the laser irradiating device according to the first aspect further includes: a movement axis which adjusts a gap between the laser irradiation section and the length measuring section in the sub-scanning direction according to an interval between the irradiation line and the planned irradiation line.

According to a third aspect of the present invention, the laser irradiating device according to the first aspect further includes: a movement axis which adjusts a gap between the laser irradiation section and the length measuring section in the sub-scanning direction, wherein the gap between the laser irradiation section and the length measuring section in the sub-scanning direction is adjusted so that a movement direction along the main scanning direction when detecting the height position of the planned irradiation line using the length measuring section is the same as a movement direction when irradiating the laser beam from the laser irradiation section with the planned irradiation line as a new planned irradiation line.

According to a fourth aspect of the present invention, there is provided a laser processing device including: the laser irradiating device according to any one of the first aspect to the third aspect, wherein the laser irradiation section performs laser processing along the irradiation line by focusing a processing laser beam on the workpiece.

According to a fifth aspect of the present invention, a laser irradiating method is provided including: irradiating a laser beam from a laser irradiation section onto an irradiation line extending in a main scanning direction of a laser irradiation surface of a workpiece; detecting a height position of the laser irradiation surface of the workpiece by focusing a distance measuring laser beam onto a planned irradiation line as an irradiation line preceding the irradiation line in a sub-scanning direction from a length measuring section provided to be movable in the main scanning direction together with the laser irradiation section and is provided at a position preceding the laser irradiation section in the sub-scanning direction; and controlling a height position of a focal point of the laser beam irradiated from the laser irradiation section when irradiating the laser beam from the laser irradiation section with the planned irradiation line as a new planned irradiation line on the basis of planned irradiation line information acquired from a detection result of the height position of the laser irradiation surface of the workpiece detected by the length measuring section.

According to the present invention, since the irradiation of the laser beam onto the irradiation line and the detection of the displacement of the planned irradiation line corresponding to the irradiation line preceding the sub-scanning direction are performed together, it is possible to acquire the planned irradiation line information in advance. Accordingly, it is possible to allow the focal point of the laser beam to reliably follow the detection result of the laser irradiation surface of the workpiece.

### BRIEF DESCRIPTION OF THE DRAWINGS

FIG. 1 is a diagram illustrating a laser processing device according to an embodiment of the present invention.

FIG. 2 is a block diagram illustrating a control system of the laser processing device according to the embodiment of the present invention.

FIG. 3 is a graph including an example (Following Example 1) in which a focal point of a laser beam is allowed to reliably follow the detection result of a laser irradiation surface of a wafer.

FIG. 4 is a graph including an example (Following Example 2) in which the focal point of the laser beam is allowed to reliably follow the detection result of the laser irradiation surface of the wafer.

FIG. 5 is a sequence diagram illustrating a laser irradiating method according to the embodiment of the present invention.

FIG. 6 is a diagram illustrating a laser processing device according to a modified example of the present invention.

FIG. 7 is a graph illustrating an example in which the height of the focal point is controlled using a distance measuring sensor coaxial with a processing laser beam.

### DETAILED DESCRIPTION OF THE INVENTION

Hereinafter, embodiments of a laser irradiating device, a laser irradiating method, and a laser processing device according to the present invention will be described with reference to the accompanying drawings.

In the following embodiments, a laser processing device (stealth dicing) that focuses (internally focuses) a laser beam inside a wafer to form a laser processing area that becomes a starting point for cutting inside the wafer will be described as an application example of laser beam irradiation control according to the present invention, but the present invention is not limited thereto. The laser beam irradiation control according to the present invention can also be applied to a laser processing device that focuses a laser beam on a laser irradiation surface (for example, a laser processing device that performs laser ablation processing). Further, the laser beam irradiation control according to the present invention can also be applied to a crack detection device that detects a front or back surface of a wafer, focuses a laser beam inside the wafer, and detects the position of a crack that has grown from the laser processing area from the front or back surface.

Furthermore, in the case of stealth dicing, a laser beam may be irradiated on the back surface of the wafer opposite to the device surface (front surface) on which devices are formed. However, in the case of laser ablation processing, the laser beam may be irradiated on the device surface. Therefore, the laser irradiation surface may be either the device surface of the wafer or the back surface thereof.

### [Laser Processing Device]

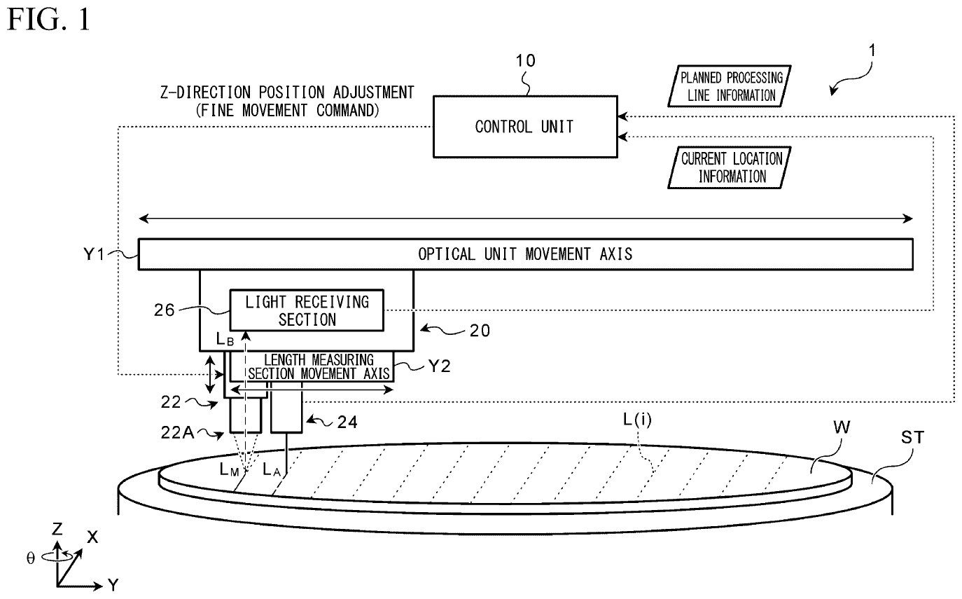

FIG. 1 is a diagram illustrating a laser processing device according to an embodiment of the present invention. Furthermore, in the following description, a three-dimensional orthogonal coordinate system in which a stage ST is parallel to the XY directions and is perpendicular to the Z direction is used.

A laser processing device 1 according to this embodiment is a device for performing laser processing that focuses (internally focuses) a processing laser beam L_{M} inside a wafer W held by suction on the stage ST to form a laser processing area that becomes a starting point for cutting inside the wafer W. As illustrated in FIG. 1, the laser irradiation surface of the wafer W is divided into grid-shaped sections by planned dividing lines L(i), and devices are formed in each section. In addition, in FIG. 1, only the planned dividing line L(i) extending along the X direction is illustrated for the sake of simplification of the drawing. The wafer W is adsorbed and held on the surface of the stage ST by a vacuum source (for example, an ejector, a pump, or the like) not illustrated.

After the laser processing area is formed along the planned dividing line L(i), the wafer W is cut along the planned dividing line L(i) by a cutting process such as expanding or breaking to form individual chips.

As illustrated in FIG. 1, the laser processing device 1 includes a control unit 10 and an optical unit 20.

The control unit 10 is a device that centrally controls each part of the laser processing device 1. The control unit 10 includes a processor (for example, Central Processing Unit (CPU), or the like), a memory (for example, Read Only Memory (ROM), a Random Access Memory (RAM), or the like), and a storage (for example, Hard Disk Drive (HDD) or Solid State Drive (SSD) or the like)

The control unit 10 has a line detection function (abnormality determination, frequency filtering, or gain setting) to be described later and a processing control function for laser processing (for example, following limit speed calculation or processing condition change).

As illustrated in FIG. 1, the optical unit 20 includes a laser processing section 22, a length measuring section 24, and a light receiving section 26.

The laser processing section 22 includes a laser oscillator which oscillates the processing laser beam L_{M} with pulses and a laser optical system having a focusing lens 22A for focusing the processing laser beam L_{M} output from the laser oscillator to a predetermined depth position inside the wafer W via the laser irradiation surface of the wafer W. As the laser oscillator, for example, a semiconductor laser excitation Nd: Yttrium Aluminum Garnet (YAG) laser, a Nd: YVO₄ laser, or the like can be used. The laser oscillator is capable of outputting the processing laser beam L_{M} having a wavelength that the wafer W absorbs (for example, a silicon wafer). The laser optical system is capable of adjusting the spot diameter of the processing laser beam L_{M} at the processing point on the laser irradiation surface of the wafer W. The laser processing section 22 is an example of a laser irradiation section.

The control unit 10 performs laser processing of the planned dividing line L(i) by controlling the laser processing section 22 to focus the processing laser beam L_{M} inside the wafer W and moving the stage ST in the processing feed direction (the main scanning direction, in other words, the X direction). Then, when the laser processing of the planned dividing line L(i) is completed, the optical unit 20 is moved in the index direction (the sub-scanning direction, in other words, the Y direction) along the optical unit movement axis (Y1 axis) to perform the laser processing of the planned dividing line L(i+1). When the laser processing is repeated and the laser processing of the planned dividing line L(i) arranged in the Y direction is completed, the stage ST is then rotated by 90° around the Z axis and the above control is repeated. Accordingly, the laser processing area can be formed along the dividing lines L(i) arranged in a grid pattern on the laser irradiation surface of the wafer W.

The length measuring section 24 includes a distance measuring sensor which measures a distance to the laser irradiation surface of the wafer W. For example, the length measuring section 24 irradiates the laser irradiation surface of the wafer W with a distance measuring laser beam L_{A}, detects the reflected light of the distance measuring laser beam L_{A} reflected by the laser irradiation surface of the wafer W, and detects the displacement (height in the Z direction) of the laser irradiation surface of the wafer W. Furthermore, the distance measuring method using the length measuring section 24 is not particularly limited, and for example, a triangular distance measuring method, a laser confocal method, a white confocal method, a spectral interference method, an astigmatism method, or the like can be adopted.

The length measuring section 24 is arranged at a position preceding the focusing lens 22A of the laser processing section 22 in the Y direction, and is scanned together with the laser processing section 22 in the X direction. Accordingly, it is possible to detect the displacement of the laser irradiation surface of the wafer W along the planned dividing line for processing (hereinafter, referred to as the planned processing line) L(j) located at the preceding position in the Y direction while performing the laser processing of the planned dividing line L(i). In this embodiment, it is assumed that the displacement of the planned processing line L(i+1) to be processed one line ahead is detected while performing the laser processing of the planned dividing line L(i) using j=i+1.

Furthermore, in this embodiment, for simplicity, the description will be made assuming that the length measuring section 24 has the same X-direction position (X coordinate) as the laser processing section 22, but it is not necessary to align the positions of the laser processing section 22 and the length measuring section 24 in the X direction.

The length measuring section 24 transmits a detection signal of the displacement of the laser irradiation surface of the wafer W along the planned processing line L(j) to the control unit 10. The control unit 10 calculates the displacement of the wafer W for each position along the planned processing line L(j) on the basis of the detection signal received from the length measuring section 24 and acquires planned processing line information including the calculated displacement of the wafer W. The planned processing line information is stored in the storage of the control unit 10. Here, the planned processing line information is an example of the planned irradiation line information.

The control unit 10 adjusts the Z-direction position of the focal point of the processing laser beam L_{M} by reading the planned processing line information from the storage when performing the laser processing using the planned processing line L(j) as a new processing target. Specifically, the control unit 10 adjusts the Z-direction position of the focal point of the processing laser beam L_{M} by outputting a fine movement command to move the focusing lens 22A in the Z direction on the basis of the planned processing line information. In this way, it is possible to eliminate the delay in adjusting the Z-direction position of the focal point of the processing laser beam L_{M} with respect to the detection of the displacement of the laser irradiation surface of the wafer W by using the pre-calculated planned processing line information. Here, the planned dividing line L(i) and the planned processing line L(j) are respectively examples of the irradiation line and the planned irradiation line. Further, the control unit 10, the laser processing section 22, and the length measuring section 24 are examples of the laser irradiating device.

The length measuring section 24 is movable in the Y direction along the length measuring section movement axis (Y2 axis) and the distance between the laser processing section 22 and the length measuring section 24 in the Y direction can be changed. Although the intervals between the planned dividing lines L(i) may differ depending on the type of wafer W, it is possible to change the gap between the laser processing section 22 and the length measuring section 24 in response to the intervals between the planned dividing lines L(i) of the wafer W by providing the length measuring section movement axis (Y2 axis) in this embodiment. Accordingly, it is possible to perform the laser processing of the planned dividing line L(i) and the detection of the displacement of the planned processing line L(j) together regardless of the type of wafer W.

Furthermore, although it is described that the intervals between the planned dividing lines L(i) of the laser irradiation surface of the wafer W are equal for simplicity of description, it is possible to perform the laser processing and the displacement detection together when the length measuring section 24 is moved along the Y2 axis according to the intervals between the planned dividing lines L(i) even when the intervals between the planned dividing lines L(i) are uneven.

Further, in this embodiment, the length measuring section 24 is moved, but either of the laser processing section 22 and the length measuring section 24 may be moved as long as the distance between them in the Y direction can be changed by relative movement.

The light receiving section 26 includes a distance measuring sensor which measures a distance to the laser irradiation surface at the processing position of the wafer W (the irradiation position of the processing laser beam L_{M}) using a distance measuring laser beam L_{B} that shares a part of the optical path with the processing laser beam L_{M}. The light receiving section 26 irradiates the distance measuring laser beam L_{B} onto the laser irradiation surface of the wafer W via the focusing lens 22A of the laser processing section 22 and detects the reflected light of the distance measuring laser beam L_{B} reflected by the laser irradiation surface of the wafer W to detect the displacement of the laser irradiation surface of the wafer W. Furthermore, the distance measuring method using the light receiving section 26 is not particularly limited, and for example, an astigmatism method can be adopted.

The light receiving section 26 transmits the detection signal of the displacement of the laser irradiation surface at the processing position of the wafer W to the control unit 10. The control unit 10 calculates the displacement of the laser irradiation surface at the processing position of the wafer W on the basis of the detection signal received from the length measuring section 24 and acquires current location information including the calculated displacement of the laser irradiation surface at the processing position of the wafer W. The current location information may be stored in the storage of the control unit 10. Furthermore, when the current location information is not used to adjust the Z-direction position of the focal point of the processing laser beam L_{M}, the light receiving section 26 may be omitted.

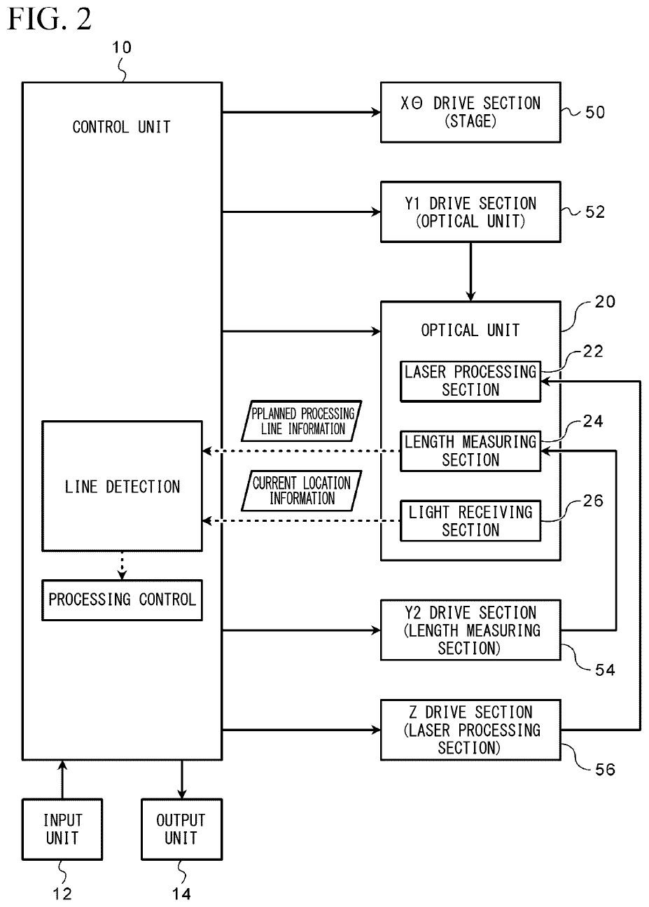

FIG. 2 is a block diagram illustrating a control system of the laser processing device according to the embodiment of the present invention.

As illustrated in FIG. 2, the control unit 10 includes an input unit 12 (for example, an operation panel or the like) which receives an operation input from a user and an output unit 14 which includes a display for displaying a Graphical User Interface (GUI) or the like for operating the laser processing device 1. The control unit 10 controls each section of the laser processing device 1 including the optical unit 20, an Xθ drive section 50, a Y1 drive section 52, a Y2 drive section 54, and a Z drive section 56.

The Xθ drive section 50 is a device which moves the stage ST in the processing feed direction (the main scanning direction, in other words, the X direction) and the rotation direction (θ direction). The Xθ drive section 50 includes a mechanism (for example, a mechanism for reciprocating linear motion, such as a ball screw mechanism, a motor, or an air guide mechanism in which a gas bearing is provided between a guide shaft and a slider) for moving the stage ST in the X direction. Further, the Xθ drive section 50 includes a mechanism (a motor or the like) for rotating the stage ST in the θ direction.

The Y1 drive section 52 includes a mechanism (for example, a mechanism for reciprocating linear motion, such as a ball screw mechanism, a motor, or an air guide mechanism in which a gas bearing is provided between a guide shaft and a slider) for moving the optical unit 20 in the index direction (the sub-scanning direction, in other words, the Y direction) along the optical unit movement axis (Y1 axis).

The Y2 drive section 54 includes a mechanism (for example, a mechanism for reciprocating linear motion, such as a mechanism including a ball screw mechanism and a motor or an air guide mechanism in which a gas bearing is provided between a guide shaft and a slider) for moving the length measuring section 24 in the index direction (the sub-scanning direction, in other words, the Y direction) along the length measuring section movement axis (Y2 axis).

The Z drive section 56 includes an actuator which moves the focusing lens 22A of the laser processing section 22 in the Z direction according to a fine movement command from the control unit 10.

Furthermore, in this embodiment, the stage ST is movable in the Xθ direction, but the optical unit 20 may be movable in the Xθ direction or both of them may be movable. Further, the stage ST may be moved in the Y direction instead of the optical unit 20. That is, the optical unit 20 and the stage ST may be relatively movable.

### Following Example 1

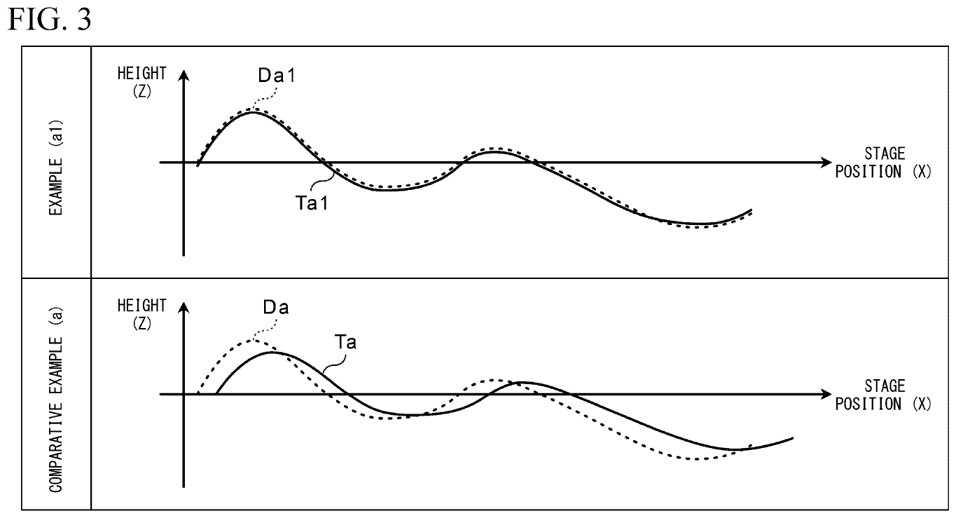

FIG. 3 is a graph including an example in which the focal point of the laser beam is allowed to reliably follow the detection result of the laser irradiation surface of the wafer. In the graph of FIG. 3, the horizontal axis indicates the scanning direction (X direction) of the processing laser beam and the vertical axis indicates the height (Z).

A dotted curve Da1 illustrated in the graph of Example (a1) indicates the height of the laser irradiation surface of the wafer W detected using the length measuring section 24 according to this embodiment. A solid curve Tal indicates a waveform when the focal point of the processing laser beam L_{M} is allowed to follow the detection result (planned processing line information) Da1 of the height of the laser irradiation surface of the wafer W.

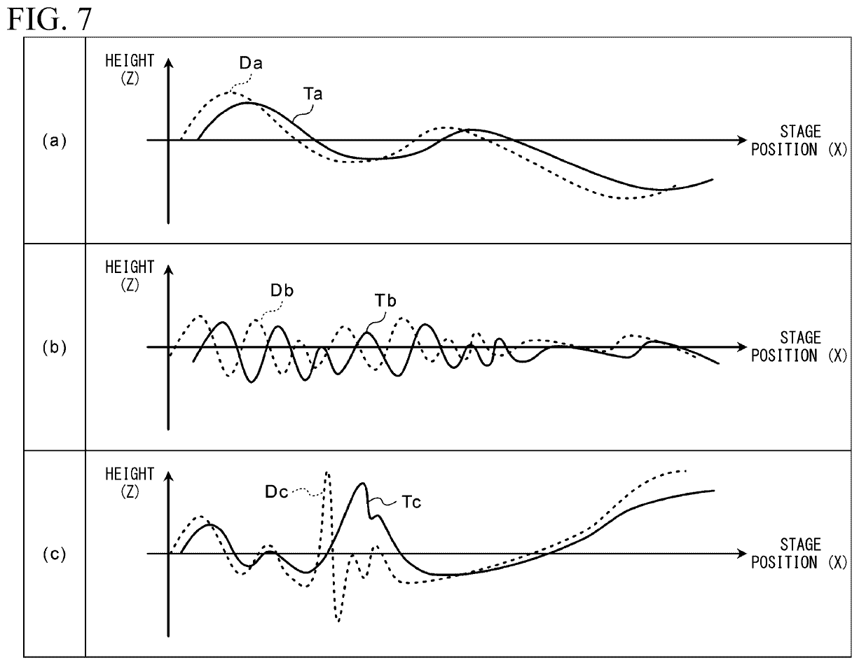

Similar to FIG. 7(a), the graph of Comparative Example (a) indicates a waveform Ta when the focal point of the processing laser beam is allowed to follow the height Da of the laser irradiation surface of the wafer W detected using the coaxial distance measuring sensor.

Comparing Example (a1) and Comparative Example (a), in Example (a1), since the z-direction height (following waveform Tal) of the focal point of the processing laser beam L_{M} is allowed to follow the planned processing line information Da1 acquired prior to the laser processing, there is no delay like Comparative Example (a). Thus, the focal point of the processing laser beam L_{M} can be allowed to reliably follow the detection result of the laser irradiation surface of the wafer W.

Further, as illustrated in FIG. 7(c), when there is an abnormality on the laser irradiation surface of the wafer, the abnormality can be detected by the line detection function of the control unit 10 before processing the planned dividing line L(i) where the abnormality exists. Then, it is possible to notify the user of the abnormality (output an alarm) via the display or speaker of the control unit 10, provide the user with guidance regarding the cause of the abnormality (for example, removal of attached foreign matter), or to interrupt the laser processing. Accordingly, it is possible to prevent unnecessary laser processing and to prevent a decrease in efficiency of laser processing.

### Following Example 2

In Following Example 1, the delay of the adjustment of the focal point of the processing laser beam L_{M} with respect to the displacement of the laser irradiation surface of the wafer W is eliminated by using the planned processing line information Da1 acquired in advance, but it is also possible to add and implement more specific processing control.

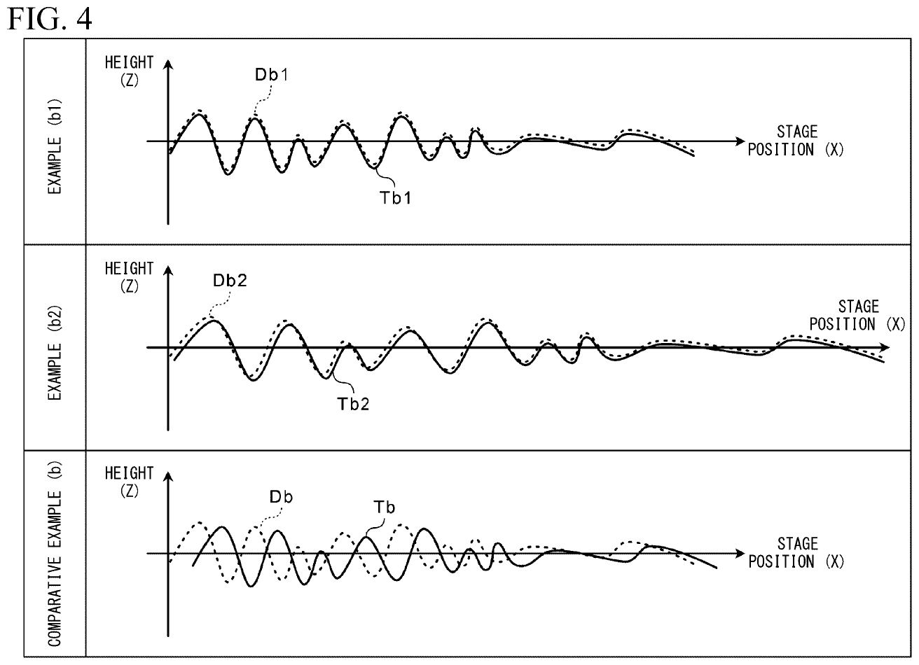

FIG. 4 is a graph including an example in which the focal point of the laser beam is allowed to reliably follow the detection result of the laser irradiation surface of the wafer. In the graph of FIG. 4, the horizontal axis indicates the position of the processing laser beam in the scanning direction (X direction) and the vertical axis indicates the height (Z).

Dotted curves Db1 and Db2 illustrated in the graphs of Examples (b1) and (b2) respectively indicate the height of the laser irradiation surface of the wafer W detected using the length measuring section 24 according to this embodiment. Solid curves Tb1 and Tb2 respectively indicate waveforms when the focal point of the processing laser beam L_{M} is allowed to follow the detection results (planned processing line information) Db1 and Db2 of the height of the laser irradiation surface of the wafer W.

Similar to FIG. 7(b), the graph of Comparative Example (b) indicates a waveform Tb when the focal point of the processing laser beam is allowed to follow the height Db of the laser irradiation surface of the wafer W detected using the coaxial distance measuring sensor.

In Example (b1), since the Z-direction height (following waveform Tb1) of the focal point of the processing laser beam L_{M} is allowed to follow the planned processing line information Db1 acquired prior to the laser processing similar to Following Example 1 of FIG. 3, there is no delay like Comparative Example (b). Thus, it is possible to prevent deterioration of the focal point of the processing laser beam L_{M} due to a phase shift between the planned processing line information Db1 and the following waveform Tb1.

Further, the control unit 10 can adjust the change rate (inclination) of the height (Z) with respect to the stage position (X) in the following waveform Tb1 by performing filtering (frequency filtering) or gain setting on the following waveform Tb1.

As the inclination of the following waveform Tb1 increases, it is necessary to increase the Z-direction position adjustment speed of the focusing lens 22A in order to allow the focal point to follow the displacement of the laser irradiation surface of the wafer W. Further, the position adjustment speed of the focusing lens 22A needs to be increased as the moving speed of the stage ST in the X direction increases. However, since there is a limit to the response speed of the actuator of the Z drive section 56, there may be a case in which the focusing lens 22A cannot be allowed to follow the displacement of the laser irradiation surface of the wafer W due to the relationship between the inclination of the following waveform Tb1 and the moving speed (processing speed) of the stage ST (hereinafter, this is referred to as the following limit).

In Example (b1), the inclination of the following waveform Tb1 is made small by setting the gain. Accordingly, it is possible to allow the focusing lens 22A to reliably follow the displacement of the laser irradiation surface of the wafer W.

Furthermore, in Example (b1), the amplitude of the following waveform Tb1 becomes smaller than the planned processing line information Db1 as a result of a decrease in the inclination of the following waveform Tb1. That is, there is a deviation between the Z-direction height of the focal point of the processing laser beam L_{M} and the laser irradiation surface of the wafer W. This deviation can be set to the minimum allowable deviation by setting the gain.

Specifically, the deviation between the Z-direction height of the focal point of the processing laser beam L_{M} and the laser irradiation surface of the wafer W due to a decrease in the inclination of the following waveform Tb1 is calculated. Then, the degree of deterioration of the focal point of the processing laser beam L_{M} due to this deviation (for example, the extent to which the focal point spreads in the Z direction) is predicted and the gain is set within the allowable limit capable of obtaining the focused light intensity required for the laser processing. When setting the gain, the material of the wafer W, the type of laser processing (for example, laser ablation processing, formation of the laser processing area, or the like), the spot diameter of the processing laser beam L_{M}, or the like may be considered.

Further, it is also possible to perform filtering (frequency filtering) according to the performance of the actuator of the Z drive section 56 or the like to eliminate the frequency that causes oscillation during following control (for example, change the period of following waveform Tb1).

As described above, according to Example (b1), it is possible to allow the focusing lens 22A to reliably follow the displacement of the laser irradiation surface of the wafer W by adjusting the inclination of the following waveform Tb1. Further, it is possible to keep the deviation within the allowable limit by obtaining the deviation between the Z-direction height of the focal point of the processing laser beam L_{M} and the laser irradiation surface of the wafer W due to the adjustment of the inclination of the following waveform Tb1, evaluating the degree of deterioration of the focal point of the processing laser beam L_{M}, and performing filtering or gain setting.

Further, in the laser processing, periodic undulations may occur due to the preceding laser processing. Even when performing the second laser processing (2nd CH) on the planned dividing line L(i) where such undulations have occurred, the focusing lens 22A can be allowed to reliably follow the undulations by adjusting the inclination of the following waveform Tb1.

Further, the focusing lens 22A may be allowed to reliably follow the following limit due to the inclination of the following waveform Tb1 by adjusting the processing speed.

The control unit 10 determines whether there is an inclination exceeding the following limit on the basis of the planned processing line information Db1. Then, when there is an inclination exceeding the following limit, the control unit 10 controls the Xθ drive section 50 to automatically change (slow down) the processing speed such that there is no inclination exceeding the following limit in the following waveform Tb2. Accordingly, as illustrated in Example (b2), the following of the focusing lens 22A can be reliably performed. In this case, there is no deviation between the Z-direction height of the focal point of the processing laser beam L_{M} and the laser irradiation surface of the wafer W. Further, in this case, it is also possible to eliminate the frequency that causes oscillation by adjusting the processing speed.

Furthermore, since the processing speed does not need to be kept constant when processing one planned dividing line L(i), the processing speed may be slowed down only in an area in which the inclination exceeds the following limit on the basis of the planned processing line information Db1.

Further, the control unit 10 may adjust the frequency of the processing laser beam L_{M} to align the pulse pitch according to the automatic change of the processing speed. For example, the number of pulses assigned to the processing laser beam L_{M} per unit length of the planned dividing line L(i) may be made uniform by reducing the frequency of the processing laser beam L_{M} while slowing down the processing speed. Accordingly, even when the processing speed is automatically changed, it is possible to align the laser processing finish.

According to this embodiment, it is possible to optimize the laser processing condition by adjusting at least one of filtering, gain setting, and processing speed according to the following limit when allowing the focusing lens 22A to follow the planned processing line information. Further, it is possible to align the laser processing finish by aligning the pulse pitch while adjusting the frequency of the processing laser beam L_{M} according to a change in the processing speed when adjusting the processing speed and thus to stably perform the laser processing.

### [Laser Irradiating Method]

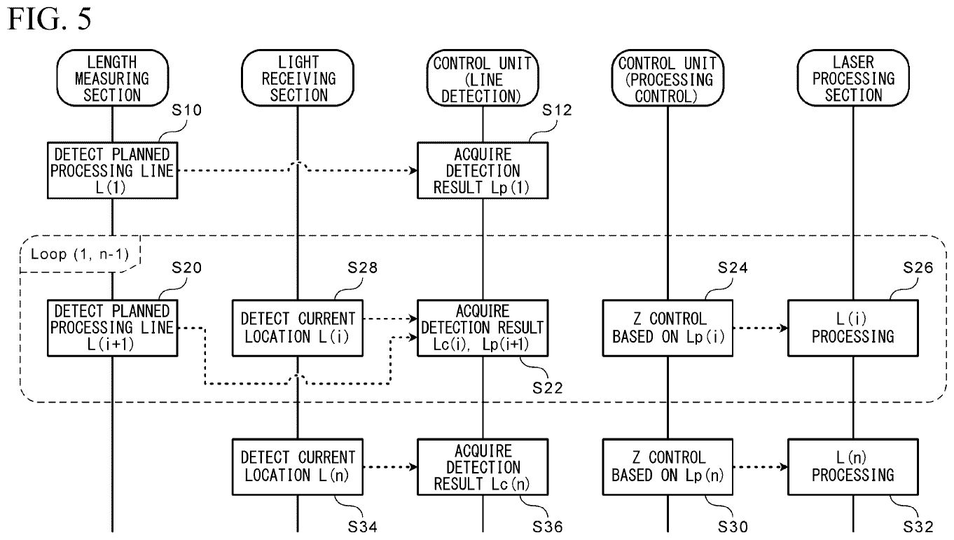

FIG. 5 is a sequence diagram illustrating a laser irradiating method according to the embodiment of the present invention. When performing the laser processing, first, the wafer W is held by suction on the stage ST, and the position of the stage ST is adjusted so that the planned dividing line L(i) is parallel to the X direction.

As described above, in this embodiment, the displacement of the planned dividing line L(i+1) one line ahead of the planned dividing line L(i) of the laser processing target is detected using the length measuring section 24. Therefore, the laser processing is not performed when detecting the displacement of the first planned dividing line L(1). Further, when the laser processing is performed on the final planned dividing line L(n), the measurement by the length measuring section 24 is not performed.

First, the length measuring section 24 is moved directly above the first planned dividing line L(1) and the Z-direction height of the planned dividing line L(1) is detected while moving the stage ST in the X direction (S10). A detection signal of the Z-direction height for each X-direction position of the planned dividing line L(1) is transmitted to the control unit 10.

The control unit 10 calculates the Z-direction height for each X direction position of the planned dividing line L(1) from the detection signal of the Z-direction height of the planned dividing line L(1). The control unit 10 stores the planned processing line information Lp(1) including information on the Z-direction height for each X-direction position of the planned dividing line L(1) in the storage (S12).

Next, the laser processing of the planned dividing line L(i) (i=1, . . . , n−1) is performed (loop of FIG. 5). That is, the optical unit 20 is moved along the Y1 axis and the length measuring section 24 is moved directly above the planned dividing line L(i+1). Then, the Z-direction height of the planned dividing line L(i+1) is detected by the length measuring section 24 while the stage ST is moved in the X direction (S20). The control unit 10 calculates the Z-direction height for each X-direction position of the planned dividing line L(i+1) and stores the height as the planned processing line information Lp(i+1) in the storage (S22).

The laser processing of the planned dividing line L(i) is performed together with the detection of the displacement of the planned dividing line L(i+1) corresponding to the planned processing line. That is, the control unit 10 performs the laser processing of the planned dividing line L(i) (S26) while adjusting the Z-direction position of the focusing lens 22A on the basis of the planned processing line information Lp(i) according to the movement of the stage ST in the X direction (S24).

Here, when the intervals of the planned dividing lines L(i) are not uniform, the length measuring section 24 may be moved along the Y2 axis to adjust the gap between the laser processing section 22 and the length measuring section 24 according to the interval between the planned dividing lines L(i) and L(i+1).

Further, the displacement of the planned dividing line L(i) is detected by the light receiving section 26 coaxial with the laser processing section 22 together with the laser processing (S28). The control unit 10 calculates the Z-direction height for each X-direction position of the planned dividing line L(i) on the basis of the detection signal of the planned dividing line L(i) from the light receiving section 26 and acquires the height as the current location information Lc(i) (S22).

The control unit 10 monitors the focusing position of the processing laser beam L_{M} by the current location information Lc(i). Furthermore, the focusing state of the processing laser beam L_{M} may be also monitored. Then, when the control unit 10 detects an abnormality at the focusing position (for example, abnormality in displacement or deviation from the planned processing line information Lp(i)), a notification to that effect or interruption of the laser processing may be provided.

When the loop illustrated in FIG. 5 is completed by repeating the above steps, next, the laser processing is performed on the planned dividing line L(n). That is, the control unit 10 performs the laser processing of the planned dividing line L(n) (S32) while adjusting the Z-direction position of the focusing lens 22A on the basis of the planned processing line information Lp(n) according to the movement of the stage ST in the X direction (S30).

Further, the displacement of the planned dividing line L(n) is detected by the light receiving section 26 coaxial with the laser processing section 22 together with the laser processing (S34). The control unit 10 calculates the Z-direction height for each X-direction position of the planned dividing line L(n) on the basis of the detection signal of the planned dividing line L(n) from the light receiving section 26 and acquires the height as the current location information Lc(n) (S36).

When the laser processing of the planned dividing line L(i) (i=1, . . . , n) is completed, next, the stage ST is rotated by 90° and the above steps are repeated. Accordingly, a laser processing area is formed inside the wafer W along the planned dividing lines L(i) arranged in a grid shape on the surface of the wafer W.

According to this embodiment, since the planned processing line information is acquired in advance, it is possible to detect the shape of the planned processing line or the abnormality of the laser irradiation surface before performing the laser processing. Furthermore, it is possible to optimize the gain during the following control according to the planned processing line information acquired in advance and to suppress the oscillation. Further, since the periodicity of the displacement of the laser irradiation surface of the wafer W can be known in advance, it is possible to perform filtering of removing specific frequencies that cause oscillation during the following control.

### Modified Example

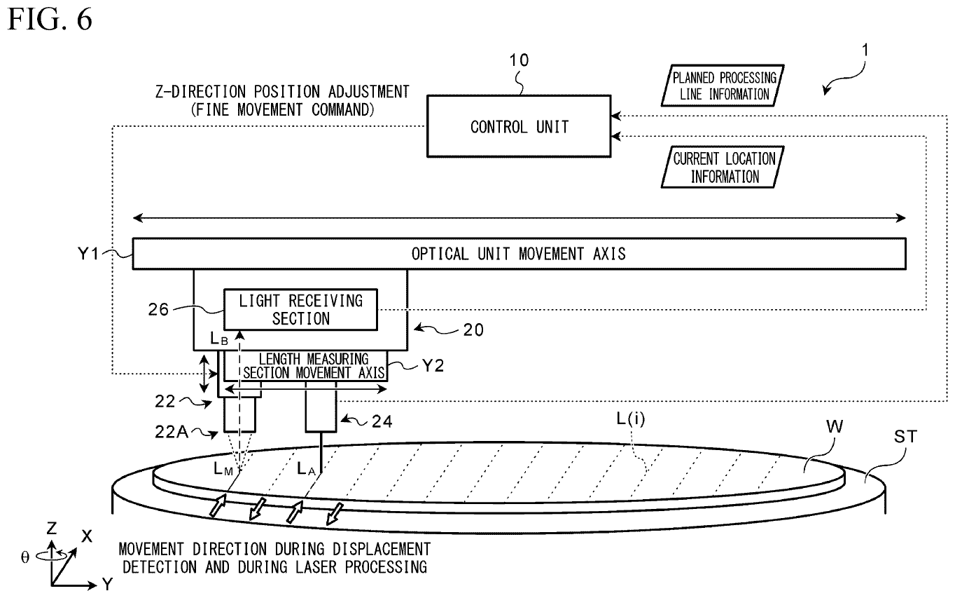

FIG. 6 is a diagram illustrating a laser processing device according to a modified example.

In the above-described embodiment, the displacement of the planned processing line L(i+1) which is one line ahead is detected together with the laser processing of the planned dividing line L(i), but in this modified example, the displacement of the planned processing line L(i+2) which is two lines ahead is detected together with the laser processing of the planned dividing line L(i).

For example, there is a case in which the laser processing is performed on the planned dividing line L(i) once (one scan processing) and the laser processing is performed while reciprocating the stage ST. In this case, since the displacement of the planned processing line L(i+2) which is two lines ahead is detected together with the laser processing of the planned dividing line L(i), the measurement can be performed in the same direction as the laser processing.

For example, when moving stage ST in the X direction, the state of vibration generated in stage ST may differ depending on the movement direction. According to the modified example, since the movement direction of the stage ST is the same during displacement detection and during laser processing as illustrated in FIG. 6, it is possible to correct the vibration component.

Furthermore, in order to perform measurement in the same direction as the laser processing, an even number of the planned processing lines may be measured and the present invention is not limited to two lines ahead.

Further, the present invention is not limited to the case of one or two lines ahead and the planned dividing line of which the displacement is detected together with the laser processing can be set arbitrarily by adjusting the gap between the laser processing section 22 and the length measuring section 24 in the Y direction. For example, it is preferable to shorten the gap (stroke size) between the laser processing section 22 and the length measuring section 24 in the Y direction as the interval between the planned dividing lines L(i) becomes short. Therefore, it is necessary to reduce the size of the laser processing section 22 and the length measuring section 24. In the above-described embodiment, the degree of freedom in designing the laser processing device 1 can be increased (layout constraints can be reduced) by providing the Y2 axis.

Further, as in Patent Document 1, when a separate axis distance measuring sensor is arranged in the processing feed direction (X direction) of the focusing lens unit, the stroke size may increase for each planned dividing line. For example, as the processing speed increases, processing time must be secured to detect displacement prior to laser processing, and the stroke size needs to be increased. On the other hand, according to the above-described embodiment and modified example, since the increase is limited to one or two lines in the index direction (Y direction), this is advantageous in terms of design or operation of the laser processing device 1.

Furthermore, the length measuring section 24 may be movable (before and after the laser processing section 22) through the laser processing section 22 (processing axis) depending on the processing feed direction. For example, when the sub-scanning of laser processing is to proceed toward the +Y side, the length measuring section 24 is moved to the +Y side of the laser processing section 22. On the other hand, when the sub-scanning of laser processing is to proceed toward the −Y side, the length measuring section 24 may be moved to the −Y side of the laser processing section 22. Further, one length measuring section 24 may be installed before and after the laser processing section 22 (on the +Y side) (two in total).

### EXPLANATION OF REFERENCES

1 Laser processing device
10 Control unit
12 Input unit
14 Output unit
20 Optical unit
22 Laser processing section
24 Length measuring section
26 Light receiving section
Y1 Optical unit movement axis
Y2 Length measuring section movement axis
50 Xθ drive section
52 Y1 drive section
54 Y2 drive section
56 Z drive section

What is claimed is:

1. A laser irradiating device comprising:
a laser irradiation section which irradiates a laser beam onto an irradiation line extending in a main scanning direction of a laser irradiation surface of a workpiece;
a length measuring section which is provided to be movable in the main scanning direction together with the laser irradiation section and is provided at a position preceding the laser irradiation section in a sub-scanning direction, the length measuring section being configured to detect a height position of the laser irradiation surface of the workpiece by focusing a distance measuring laser beam on a planned irradiation line corresponding to an irradiation line that precedes the irradiation line in the sub-scanning direction; and
a control unit which controls a height position of a focal point of the laser beam irradiated from the laser irradiation section when irradiating the laser beam from the laser irradiation section with the planned irradiation line as a new planned irradiation line on the basis of planned irradiation line information acquired from a detection result of the height position of the laser irradiation surface of the workpiece detected by the length measuring section.

2. The laser irradiating device according to claim 1, further comprising:
a movement axis which adjusts a gap between the laser irradiation section and the length measuring section in the sub-scanning direction according to an interval between the irradiation line and the planned irradiation line.

3. The laser irradiating device according to claim 1, further comprising:
a movement axis which adjusts a gap between the laser irradiation section and the length measuring section in the sub-scanning direction,
wherein the gap between the laser irradiation section and the length measuring section in the sub-scanning direction is adjusted so that a movement direction along the main scanning direction when detecting the height position of the planned irradiation line using the length measuring section is the same as a movement direction when irradiating the laser beam from the laser irradiation section with the planned irradiation line as a new planned irradiation line.

4. A laser processing device comprising:
the laser irradiating device according to claim 1,
wherein the laser irradiation section performs laser processing along the irradiation line by focusing a processing laser beam on the workpiece.

5. A laser irradiating method comprising:
irradiating a laser beam from a laser irradiation section onto an irradiation line extending in a main scanning direction of a laser irradiation surface of a workpiece;
detecting a height position of the laser irradiation surface of the workpiece by focusing a distance measuring laser beam onto a planned irradiation line as an irradiation line preceding the irradiation line in a sub-scanning direction from a length measuring section provided to be movable in the main scanning direction together with the laser irradiation section and is provided at a position preceding the laser irradiation section in the sub-scanning direction; and
controlling a height position of a focal point of the laser beam irradiated from the laser irradiation section when irradiating the laser beam from the laser irradiation section with the planned irradiation line as a new planned irradiation line on the basis of planned irradiation line information acquired from a detection result of the height position of the laser irradiation surface of the workpiece detected by the length measuring section.
